(19) United States
(12) Patent Application Publication
(10) Pub. No.: US 2025/0239397 A1
(43) Pub. Date: Jul. 24, 2025

(54) TRANSFORMER PACKAGES WITH MAGNETIC CORE SUSPENSION

(71) Applicant: Allegro MicroSystems, LLC, Manchester, NH (US)

(72) Inventor: William P. TAYLOR, Amherst, NH (US)

(73) Assignee: Allegro MicroSystems, LLC, Manchester, NH (US)

(21) Appl. No.: 18/417,582

(22) Filed: Jan. 19, 2024

(51) Int. Cl. H01F 27/32; H01F 27/24; H01F 27/38; H01F 41/04; H01L 23/64

(52) U.S. Cl. CPC H01F 27/327; H01F 27/24; H01F 27/38; H01F 41/04; H01L 23/645

(57) ABSTRACT

According to one aspect of the present disclosure, a transformer based integrated circuit (IC) package includes a portion including a recess. In some embodiments, a magnetic core disposed in the recess, wherein the recess is configured to provide a space between an interior surface of the recess and an exterior surface of the magnetic core, wherein the magnetic core includes a soft ferromagnetic material. In some embodiments, two or more support structures disposed in the recess and connected to the magnetic core and package portion. In some embodiments, a plurality of conductive traces forming first and second coils disposed about the magnetic core, wherein the first and second coils and magnetic core are configured as a transformer. In some embodiments, a molding material is configured to encapsulate a surface of the package portion and the transformer, wherein the molding material is configured to form a package body.

### BACKGROUND

Voltage isolation can be used for electronic packages having circuit components with two separate voltage levels connected to the electrical connections of the package. Galvanic isolation typically includes electrical isolation coupled with lack of direct electrical contact between the circuit components. Such galvanic isolation can be used to separate circuits in order to protect users from coming into direct contact with hazardous voltages. Galvanic isolation may also be used to simplify circuit design, reduce cost or improve system performance.

Magnetic coupling typically relies on use of a transformer to couple, yet galvanically separate, circuits on the different sides of the transformer, typically referred to as the primary and secondary sides. Transformers used for magnetic-coupling isolation barriers typically utilize a magnetic core to provide a magnetic path to channel flux created by the currents flowing in the primary and secondary sides of the transformer.

Magnetic-coupling isolation barriers have been shown to have various drawbacks, including manufacturing problems, for integrated circuit (IC) packages due to the included magnetic core. IC packaging techniques can be used for isolated voltage circuits like ones utilizing magnetic coupling. The packaging techniques may be used to integrate one or more semiconductor dies into a module or package, for example by encapsulating the die with a non-conductive, insulating mold material.

The term “clearance” refers to the shortest distance through air between two conductive parts, such as the primary and secondary leads. The term “creepage” refers to the shortest distance between two conductive parts along the surface of any insulation material common to both parts. The spacing distance between components that are required to withstand a given working voltage (i.e., the highest voltage level that insulation under consideration can be subjected to when a device is operating under normal use) is specified in terms of creepage and clearance. Meeting specified creepage and clearance requirements can become challenging, particularly as package dimensions are reduced.

### SUMMARY

According to one aspect of the present disclosure, a transformer based integrated circuit (IC) package includes a first portion, e.g., a first substrate portion, including a recess. In some embodiments, a magnetic core disposed in the recess, wherein the recess is configured to provide a space between an interior surface of the recess and an exterior surface of the magnetic core, wherein the magnetic core includes a soft ferromagnetic material. In some embodiments, two or more support structures disposed in the recess and connected to the magnetic core and first portion. In some embodiments, a plurality of conductive traces forming first and second coils disposed about the magnetic core, wherein the first and second coils and magnetic core are configured as a transformer. In some embodiments, a molding material is configured to encapsulate a surface of the first portion and the transformer, wherein the molding material is configured to form a package body.

According to another aspect of the present disclosure, a method of making a transformer based integrated circuit (IC) package, including providing a first portion, e.g., a first substrate portion, including a recess (cavity or depression). In some embodiments, a method also includes providing a magnetic core disposed in the recess, wherein the recess is configured to provide a space between an interior surface of the recess and an exterior surface of the magnetic core, wherein the magnetic core includes a soft ferromagnetic material. In some embodiments, a method also includes providing two or more support structures disposed in the recess and connected to the magnetic core and first portion. In some embodiments, a method also includes providing a plurality of conductive traces forming first and second coils disposed about the magnetic core, wherein the first and second coils and magnetic core are configured as a transformer. In some embodiments, a method also includes providing a molding material configured to encapsulate a surface of the first portion and the transformer, wherein the molding material is configured to form a package body.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1A is a side view of a cross section of an integrated circuit (IC) package configuration with a layered transformer core suspended with support structures, in accordance with the present disclosure;

FIG. 1B is a side view of a cross section of an IC package with the IC package configuration of FIG. 1A and a package body, in accordance with the present disclosure;

FIG. 2 is top view of a cross section of an IC package configuration with a transformer core suspended with optional variations of support structures formed in an L-shape, in accordance with the present disclosure;

FIG. 3 is a side view of a cross section of an IC package configuration with a transformer core suspended with support structures in a molded package, in accordance with the present disclosure;

FIG. 4 is top view of a cross section of an IC package configuration with a transformer core suspended with optional similar support structures formed in an L-shape, in accordance with the present disclosure;

FIG. 5 is a side view of a cross section of an IC package configuration with a layered transformer core suspended with support structures connected to the transformer core at a middle layer, in accordance with the present disclosure; and

FIG. 6 is a method of forming an integrated circuit (IC) package configuration with a transformer core suspended with support structures, in accordance with the present disclosure.

### DETAILED DESCRIPTION

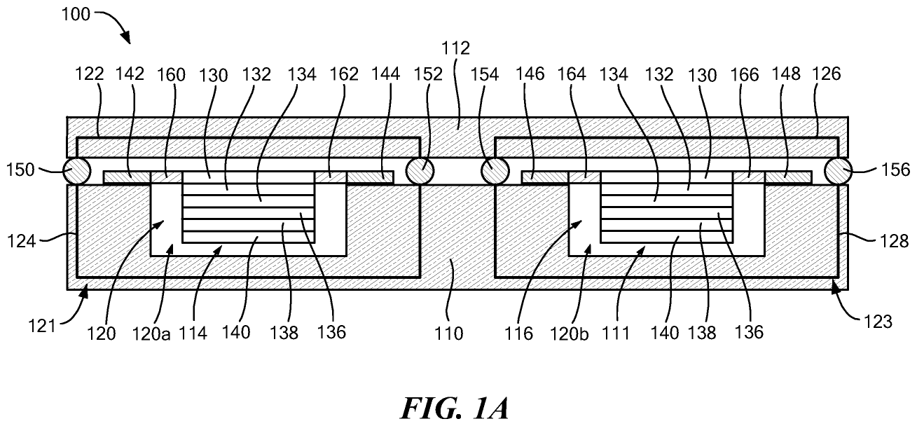

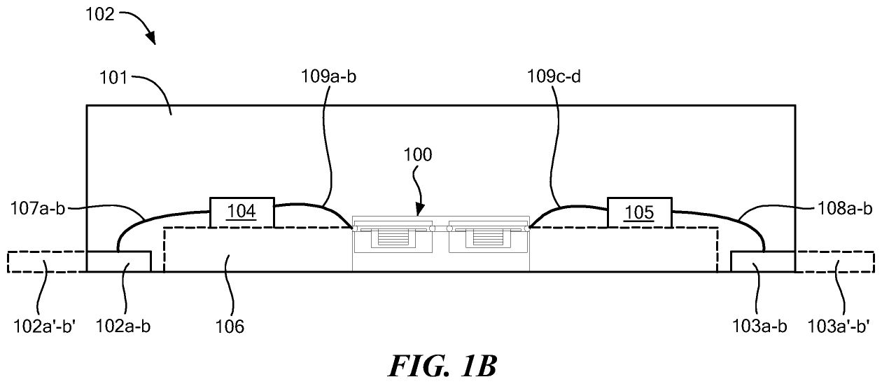

Referring now to FIG. 1A, an example voltage isolated integrated circuit (IC) package 100 is shown as including a first portion (bottom portion) 110 and a second portion (top or cover portion) 112 mechanically coupled together. As described in further detail below, IC package 100 includes an isolation transformer that can provide galvanic isolation (voltage isolation) between first (primary) and second (secondary) sides of the transformer. FIG. 1B is a side view of an IC package with the IC package 100 and a package body 101.

First portion 110 can be or include a printed circuit board (PCB), a ceramic (such as high temperature co-fired ceramic (HTCC) or a low temperature co-fired ceramic (LTCC)), glass, a molded lead frame, such as for example a lead frame with an epoxy mold compound or other suitable first portion for use in an application system. According to an aspect of the disclosure, first portion 110 can implement or include a molded lead frame (e.g., a lead frame with an epoxy mold compound). The first portion 110 includes a recess 111 (shown with cross sections 114, 116), which is configured to receive a magnetic core 120 (shown with cross sections 120a, 120b). The magnetic core 120 includes a soft ferromagnetic material.

For a first portion formed from a PCB, there may be layers (which are not shown in FIG. 1A) that form the recess or cavity (recess and cavity may be used interchangeably throughout this disclosure). The layers are formed from a PCB material, for example but not limited to FR4, FR5, or a polyimide material in a flex circuit. The layers may include a copper layer, the copper layer may have patterned traces that form the conductive traces. The recess may be formed by holes or cut outs in some or all of the PCB layers (e.g., FR4, FR5, or polyimide material layers) before the layers are laminated or adhered together in the PCB like fabrication process. In a PCB fabrication process it is possible to form the transformer structure as the PCB layers are fabricated and then the vias for the transformer can be made by a process such as through hole vias.

Support structures 160, 162, 164, 166 are disposed in the recess 111 and are connected to the magnetic core 120 and anchors 142, 144, 146, 148 positioned on the first portion 110. The support structures 160, 162, 164, 166 are configured to reduce a mechanical stress on the magnetic core 120. The support structures 160, 162, 164, 166 allow for the suspension of the magnetic core 120 in the recess 111.

The recess 111 is configured to provide a space between an interior surface of the recess 111 and an exterior surface of the magnetic core 120. The space comprises a gap between the interior surface of the recess 111 and the exterior surface of the magnetic core 120. The recess 111 allows the magnetic core 120 to undergo reduced mechanical constraint changes in size due to magnetostriction and thermal expansion. The space is included to allow the magnetic core 120 to undergo size changes due to magnetostriction and thermal expansion during operation of the transformer without being constrained or substantially constrained, thus, providing for improved magnetic performance.

The magnetic core 120 may have a closed-loop shape. A cross-sectional side view of the magnetic core 120 positioned in the recess 111 is shown in FIG. 1A, including a first core cross section 120a and a second core cross section 120b. The first core cross section 120a of the magnetic core 120 is positioned in a first recess cross section 114. The second core cross section 120b of the magnetic core 120 is configured in a second recess cross section 116.

The magnetic core 120 includes one or more layers 130, 132, 134, 136, 138, 140. A first layer 130, which may herein be referred to as a ‘top layer’, is disposed on a second layer 132. The second layer 132 is disposed on a third layer 134. The third layer 134 is disposed on a fourth layer 136. The fourth layer 136 is disposed on a fifth layer 138. The fifth layer 138 is disposed on a sixth layer 140. One of the one or more layers 130, 132, 134, 136, 138, 140 may be a spacer layer. The spacer layer may be a stamped material, or material that is etched, milled, molded, or otherwise fabricated. A molded material may be a ferrite or metal alloy. One or more spacer layers formed of the stamped material may be mechanically connected. The spacer layer may be epoxy, glue, a tape layer, or another kind of adhesive connection. Further, there may be one or more adhesive layers between one or more of the core layers. The adhesive layers may be formed from a non-conductive material that will reduce eddy currents.

A plurality of conductive traces 122, 124, 126, 128 are disposed about the magnetic core 120. A first conductive trace 122 is disposed in the second portion 112 and a second conductive trace 124 is disposed in the first portion 110. The first conductive trace 122 and second conductive trace 124 are connected through a first connection 150 and a second connection 152. The first connection 150 and the second connection 152 may be a via or a conductive trace. The first conductive trace 122 and second conductive trace 124 form one or more windings (one is shown) of a first coil 121 disposed around the first core cross section 120a. While the first coil 121 is shown with a single winding (loop), it will be understood that one or more additional windings (loops) of the first coil 121 may extend (wound) about the core 120 in a direction into and/or out of the plane of FIG. 1A.

A third conductive trace 126 is disposed in the second portion 112 and a fourth conductive trace 128 is disposed in the first portion 110. The third conductive trace 126 and fourth conductive trace 128 are connected through a third connection 154 and a fourth connection 156. The third connection 154 and fourth connection 156 may be a conductive ball or pillar, via or a conductive trace. The third conductive trace 126 and fourth conductive trace 128 form one or more windings (one is shown) of a second coil 123 disposed around the second core cross section 120b. While the second coil 123 is shown with a single winding (loop), it will be understood that one or more additional windings (loops) of the second coil 123 may extend (wound) about the core 120 in a direction into and/or out of the plane of FIG. 1A. The plurality of conductive traces 122, 124, 126, 128 which form the first and second coils 121, 123 and the magnetic core 120 are configured as a transformer. Although electrical connections 150, 152, 154, 156 are shown as more of a ball connection other connections are possible. In some embodiments, e.g., a PCB implementation, the electrical connections 150, 152, 154, 156 may be formed in or include vias (not shown) from the top traces 122, 126 to lower electrical traces 124, 128. Electrical connections, which may be a bonding pad or a pin connection, may also be on a surface of the transformer, for example the top surface of second portion 112. The bonding pads or pin connections may be used to connect the transformer to an integrated circuit die or the leads or pins of an IC package.

The second portion 112 is configured to encapsulate the surface of the first portion 110 and the transformer, to form a package body. The second portion 112 may be a mold material, including, but not limited to epoxy mold compound or a plastic material or a Printed circuit board material, such as but not limited to FR4, or a ceramic material. The second portion 112 may be another PCB, a molded lead frame portion, or a ceramic portion which contain or support electrical traces or current conductors. Further, an insulator may be included with the trace in the top portion encompassed by an insulator, such as silicone.

Anchors 142, 144, 146, 148 are positioned on either side of the recess 111. A first anchor 142 is positioned on the first portion 110 on a side of the first recess cross section 114 and a second anchor 144 is positioned on the first portion 110 on an opposing side of the first recess cross section 114. A third anchor 146 is positioned on the first portion 110 on a side of the second recess cross section 116 and a fourth anchor 148 is positioned on the first portion 110 on an opposing side of the second recess cross section 116. The anchors 142, 144, 146, 148 are positioned adjacent to the first layer 130, but are not in contact with the magnetic core 120. The anchors may be formed from the same material as the core. The anchors may be made out of a PCB material, for example but not limited to FR4, FR5, or a polyimide material. The anchors may have the same thickness as the support structures and/or the layer of the core the anchor connects to.

The support structures may be formed, such as through a stamping process, or material that is etched, milled, molded, or otherwise fabricated, at the same time as the anchors and the core layers. In an embodiment the anchors, a core layer, and the support structures may have the same thickness. In another embodiment, the support structures have the same thickness as the anchors. In another embodiment the support structures may have a thickness less than that of the core or anchors. The support structures may be made of the same material as the anchors. In some embodiments, the support structures may be formed from a single continuous material layer disposed in the recess. In some embodiments, the support structures are formed from separate material layers disposed in the recess.

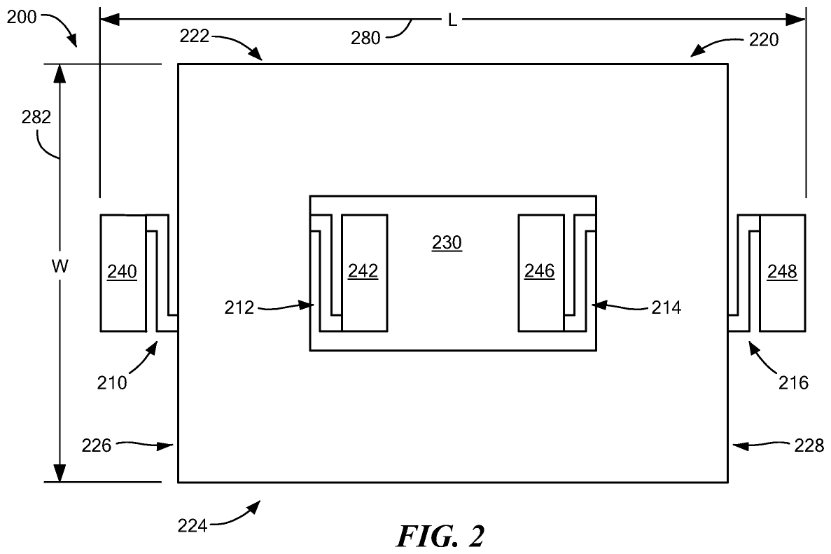

A first support structure 160 is disposed in the first recess cross section 114 and is connected to the first anchor 142 and the first layer 130. A second support structure 162 is disposed in the first recess cross section 114 and is connected to the second anchor 144 and the first layer 130. A third support structure 164 is connected to the third anchor 146 and the first layer 130. A fourth support structure 166 is connected to the fourth anchor 148 and the first layer 130. The support structures 160, 162, 164, 166 may extend from the first portion 110 to the magnetic core 120 in a straight shape, as shown, or may be in an L-shape, as will be discussed in FIG. 2.

FIG. 1B is a side view of an IC package 102 with the IC package 100 and a package body 101. The molding material can encapsulate a surface of the first portion 110 to form the package body 101.

Package body 101 includes lead pairs (conductive pads) 102a-b and 103a-b. Alternate extended lead pair configurations 102a′-b′ and 103a′-b′ are shown. Package 102 can include substrate 106 receiving (supporting) first and second IC dies (dice) 104, 105. Substrate 106 is connected to and may be the same as first portion 110. First and second IC dies 104, 105 can be connected to lead pairs 102a-b and 103a-b by conductive elements 107a-b and 108a-b (e.g., wire bonds), respectively. Accordingly, package 102 can include IC package configuration 100 having first and second coils 121, 123 disposed in substrate 106. First and second coils 121, 123 can be connected to first and second dies 104, 105, e.g., by conductive elements (wire bonds) 109a-b and 109c-d, respectively.

In an example embodiment to form the IC package configuration using a PCB like fabrication process, a copper layer is formed with patterned traces. An insulator layer comprising FR4 is formed on the copper layer. One or more additional FR4 layers with cut outs are formed on the insulator layer. The cutout provides the recess. The cutout may be formed by leaving a region of the material out while forming the one or more additional FR4 layers before pressing.

One or more anchors are then formed on the FR4 layers. A support structure layer is then added in, wherein the support structures are formed from a single structure. A core layer is then formed in the recess with the same thickness as the anchors and support structures. One or more additional core layers may be added in by forming additional Fr4 layers with cut outs to provide a recess appropriate to fit the additional core layers. An FR4 layer with a cut out is formed on the core layer. An insulator layer comprising FR4 is formed on the FR4 layer. A copper layer with patterned traces is formed on the insulator layer. The layers are pressed together under pressure and temperature in order to form the PCB. One or more holes are then drilled through the PCB to make vias to form the vertical portions of the connections.

Referring now to FIG. 2, a top view of a voltage isolated integrated circuit (IC) package configuration 200 includes a core 220 (like magnetic core 120) mechanically coupled to support structures 210, 212, 214, 216 (like support structures 160, 162, 164, 166) and anchors 240, 242, 246, 248 (like anchors 142, 144, 146, 148). The support structures 210, 212, 214, 216 are L-shaped. The support structures 210, 212, 214, 216 may be the same or different in shape and may connect to the core 220 in the same or a different location along a width 282 of the core 220.

The core 220 includes four continuous sides 222, 224, 226, 228 and a center area 230. Moving clockwise along the core 220, a first side 222 is formed along a length 280 of the core 220 and is connected to a second side 228 and a fourth side 226. The first side 222 is directly opposite and parallel from a third side 224. The third side 224 is formed along the length 280 of the core 220 and is directly connected to the fourth side 226 and the second side 228. The second side 228 and the fourth side 226 are formed along the width 282 of the core 220 and are opposite and parallel from each other.

The anchors 240, 242, 246, 248 are formed along the width 282 and positioned parallel to the second side 228 and the fourth side 226 and perpendicular to the first side 222 and the third side 224. A first anchor 240 is positioned adjacent to the fourth side 226 on an outside of the core 220. A second anchor 242 is positioned adjacent to the fourth side 226 on the inside center area 230. A third anchor 246 is positioned adjacent to the second side 228 on the inside center area 230. A fourth anchor 248 is positioned adjacent to the second side 228 on the outside area of the core 220. The anchors 240, 242, 246, 248 are smaller in length 280 and width 282 than the sides 222, 224, 226, 228. Other anchor sizes and configurations are also possible. In an embodiment, the anchor may encircle the recess or opening for the magnetic core, such as in embodiments where a magnetic material layer is used. In an embodiment, such as one where a PCB is used, the anchor may encircle the recess or opening for the magnetic core to allow the thickness of the anchor to be more uniform around the recess and to better incorporate the fabrication of the anchor into the PCB fabrication process. Similar anchor construction may be useful in other constructions as well, such as but not limited to the molded lead frame construction.

The support structures 210, 212, 214, 216 are connected to the anchors 240, 242, 246, 248 and the sides 222, 224, 226, 228. The pieces of the support structures 210, 212, 214, 216 may be positioned to form an L-shape, as is shown in FIG. 2. An L-shaped support structure may be useful when the transformer is built on a PCB and wire bonds go over a portion of the core 220. The support structures may be formed in other shapes, such as a straight line or other shaped supports.

A first support structure 210 connects first anchor 240 to fourth side 226 on the outside of the core 220. A second support structure 212 connects the second anchor 242 to the fourth side 226 in the inside center area 230 of the core 220. A third support structure 214 connects the third anchor 246 to the second side 228 in the inside center area 230 of the core 220. A fourth support structure 216 connects the fourth anchor 248 to the second side 228 on the outside of the core 220.

The location of the connection of the support structures 210, 212, 214, 216 to the side 222, 224, 228, 226 can be modified such that some of the support structures 210, 216 are connected in a different location along the width 282 compared to the other support structures 212, 214. As shown in FIG. 2, some support structures 210, 216 are positioned to connect to the fourth side 226 in a different location along the width 282 of the core 220 compared to the other support structures 212, 214. The first support structure 210 connects to the fourth side 226 and the fourth support structure 216 connects to the second side 228 closer to the third side 224, while the other support structures 212, 214 connect to their respective sides 226, 228 closer to the first side 222. In an embodiment, first support structure 210 connects to the core 220 at a different width location, which may be different than the connection of the support structures 212, 214, 216 to the core 220. The support structures 210, 212, 214, 216 may be the same size in length 280 and width 282 as the anchors 240, 242, 246, 248 or may be larger or smaller in size. In an embodiment the anchors 240, 248 are connected and anchors 242, 246 are connected. In an embodiment, the anchors may have a thickness less than that of the support structures or the core.

It will be appreciated by those of ordinary skill in the art that although the voltage isolated integrated circuit (IC) package configuration 200 is shown with four support structures 210, 212, 214, 216, respectively, other numbers of support structures are possible. For example, eight support structures may be used with each support structure connected side of the core. It will also be apparent that support structures may connect to sides 222, 224 along the length 280 of the recess.

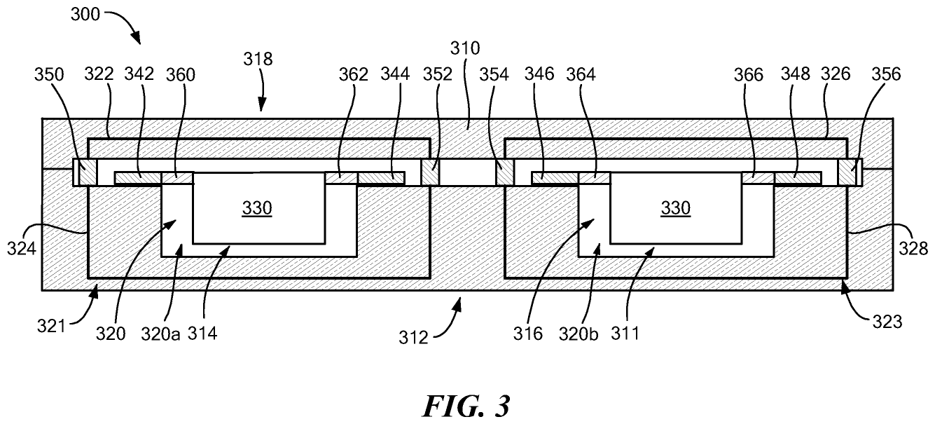

Referring now to FIG. 3, a voltage isolated integrated circuit (IC) package configuration 300 includes a portion 310 comprising a recess 311 (like recess 111) which is configured to receive a magnetic core 320 (like magnetic core 120). Portion 310 comprises a first portion 312 and a second portion 318. The portion 310 is configured to encapsulate and support the suspended magnetic core 320 to form a package body.

The magnetic core 320 may have a shape that includes a closed loop. A cross-sectional side view is shown in FIG. 3 with core 320 shown as having a first core cross section 320a and a second core cross section 320b. The first core cross section 320a is positioned in a first recess cross section 314, which may be similar to first recess cross section 114. The second core cross section 320b is configured in a second recess cross section 316, which may be similar to second recess cross section 116. The magnetic core 320 is configured as one layer 330. In an embodiment the core 320 thickness may be the same as the anchors 343, 344, 346, 248, and the support structures 360, 362, 364, 366. In an embodiment, the magnetic core may be a molded ferrite (further, legs or supports may be disposed at the top of the core 320).

A plurality of conductive traces 322, 324, 326, 328 are disposed about the magnetic core 320. A first conductive trace 322 and a second conductive trace 324 are positioned in the portion 310. The first conductive trace 322 and second conductive trace 324 are connected through a first connection 350 and a second connection 352. The first connection 350 and the second connection 352 may be or include any suitable connective conductive stricture, e.g., a via (as shown), a conductive trace, and/or solder structure (e.g., solder ball). The first conductive trace 322 and second conductive trace 324 form one or more windings (one is shown) of a first coil 321 disposed around the first core cross section 320a. While the first coil 321 is shown with a single winding (loop), it will be understood that one or more additional windings (loops) of the first coil 321 may extend (wound) about the core 320 in a direction into and/or out of the plane of FIG. 3.

A third conductive trace 326 and a fourth conductive trace 328 are positioned in the portion 310. The third conductive trace 326 and fourth conductive trace 328 are connected through a third connection 354 and a fourth connection 356. The third connection 354 and fourth connection 356 may be or include any suitable connective conductive stricture, e.g., a via (as shown), a conductive trace, and/or solder structure (e.g., solder ball). The third conductive trace 326 and fourth conductive trace 328 form one or more windings (one is shown) of a second coil 323 disposed around the second core cross section 320b. While the second coil 323 is shown with a single winding (loop), it will be understood that one or more additional windings (loops) of the second coil 323 may extend (wound) about the core 320 in a direction into and/or out of the plane of FIG. 3. The plurality of conductive traces 322, 324, 326, 328 which form the first and second coils and the magnetic core 320 are configured as a transformer.

Anchors 342, 344, 346, 348 are positioned on either side of the recess 311. A first anchor 342 is positioned on the portion 310 on a side of the first recess cross section 314 and a second anchor 344 is positioned on the portion 310 on an opposing side of the first recess cross section 314. A third anchor 346 is positioned on the portion 310 on a side of the second recess cross section 316 and a fourth anchor 348 is positioned on the portion 310 on an opposing side of the second recess cross section 316. The anchors 342, 344, 346, 348 are not in contact with the magnetic core 320.

Support structures 360, 362, 364, 366 are disposed in the recess 311 and are connected to the magnetic core 320 and the anchors 342, 344, 346, 348 positioned on the portion 310. The support structures 360, 362, 364, 366 are configured to reduce a mechanical stress on the magnetic core 320.

A first support structure 360 is disposed in the first recess cross section 314 and is connected to the first anchor 342 and the layer 330. A second support structure 362 is disposed in the first recess cross section 314 and is connected to the second anchor 344 and the layer 330. A third support structure 364 is connected to the third anchor 346 and the layer 330. A fourth support structure 366 is connected to the fourth anchor 348 and the first layer 330. The support structures 360, 362, 364, 366 may extend from the mold material to the magnetic core 320 in a straight shape.

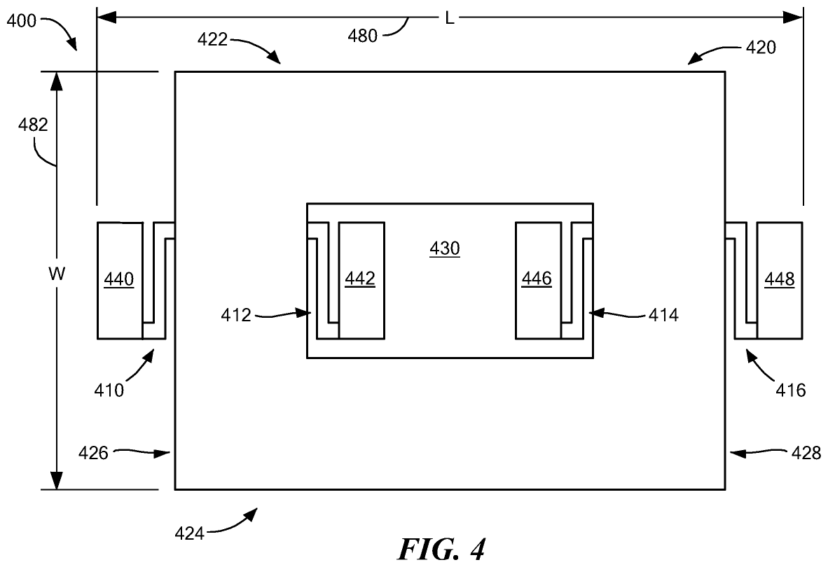

Referring now to FIG. 4, a top view of a voltage isolated integrated circuit (IC) package configuration 400 includes a core 420 (like magnetic core 120) mechanically coupled to support structures 410, 412, 414, 416 (like support structure 160, 162, 164, 166) and anchors 440, 442, 446, 448 (like anchors 142, 144, 146, 148). The support structures 410, 412, 414, 416 are L-shaped. While support structures 410, 412, 414, 416 may be the same or different in shape, each connects to the core 420 in the same location along a width 482 of the core 420.

The core 420 includes four continuous sides 422, 424, 426, 428 and a center area 430. Moving clockwise along the core 420, a first side 422 is formed along a length 480 of the core 420 and is connected to a second side 428 and a fourth side 426. The first side 422 is directly opposite and parallel from a third side 424. The third side 424 is formed along the length 480 of the core 420 and is directly connected to a fourth side 426 and the second side 428. The second side 428 and the fourth side 426 are formed along the width 482 of the core 420 and are opposite and parallel from each other.

The anchors 440, 442, 446, 448 are formed along the width 482 and positioned parallel to the second side 428 and the fourth side 426 and perpendicular to the first side 422 and the third side 424. A first anchor 440 is positioned adjacent to the fourth side 426 on an outside of the core 420. A second anchor 442 is positioned adjacent to the fourth side 426 on the inside center area 430. A third anchor 446 is positioned adjacent to the second side 428 on the inside center area 430. A fourth anchor 448 is positioned adjacent to the second side 428 on the outside area of the core 420. The anchors 440, 442, 446, 448 are smaller in length 480 and width 482 than the sides 422, 424, 426, 428.

The support structures 410, 412, 414, 416 are connected to the anchors 440, 442, 446, 448 and the sides 422, 424, 426, 428. The pieces of the support structures 410, 412, 414, 416 may be positioned to form an L-shape. A first support structure 410 connects first anchor 440 to fourth side 426 on the outside of the core 420. A second support structure 412 connects the second anchor 442 to the fourth side 426 in the inside center area 430 of the core 420. A third support structure 414 connects the third anchor 446 to the second side 428 in the inside center area 430 of the core 420. A fourth support structure 416 connects the fourth anchor 448 to the second side 428 on the outside of the core 420.

The location of the connection of the support structures 410, 412, 414, 416 to the side 422, 424, 428, 426 can be modified such that the support structures 410, 412, 414, 416 are connected in the same location along the width 482. As shown in FIG. 4, the support structures 410, 412, 414, 416 are positioned to connect closer to the first side 422 along the width 482 and in the same location along the width 482.

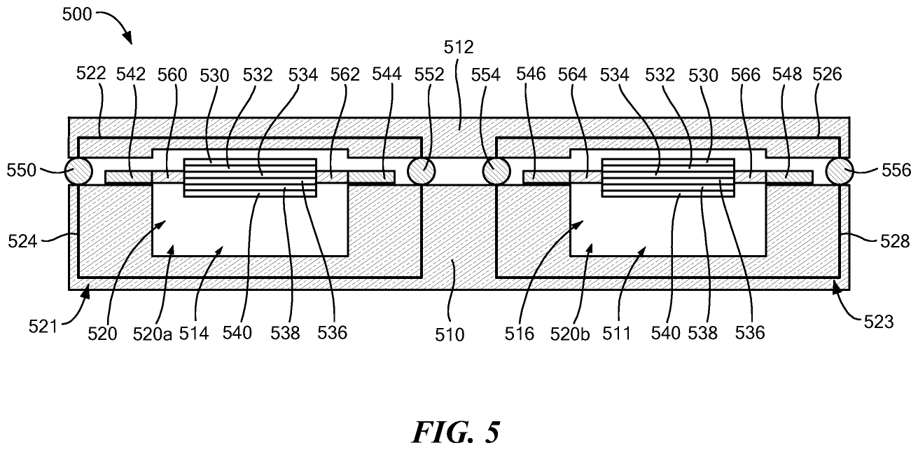

Referring now to FIG. 5, a voltage isolated integrated circuit (IC) package configuration 500 includes a first portion (like first portion 110) and a second portion 512 (like second portion 112) mechanically coupled together. The first portion 510 and second portion 512 include a recess 511 (e.g., one similar to recess 111) which is configured to receive a magnetic core 520 (like magnetic core 120).

The magnetic core 520 may have a closed-loop shape. A cross-sectional side view of the magnetic core 520 is shown in FIG. 5, including a first core cross section 520a and a second core cross section 520b. The first core cross section 520a is positioned in a first recess cross section 514. The second core cross section 520b is configured in a second recess cross section 516. The recess 511 is configured to provide a space between an interior surface of the recess 511 and an exterior surface of the magnetic core 520. The space comprises a gap between the interior surface of the recess 511 and the exterior surface of the magnetic core 520.

The magnetic core 520 includes one or more layers 530, 532, 534, 536, 538. A first layer 530 is disposed on a second layer 532. The second layer 532 is disposed on a third layer 534. The third layer 534 is disposed on a fourth layer 536. The fourth layer 536 is disposed on a fifth layer 538. At least one of the one or more layers 530, 532, 534, 536, 538 may be a spacer layer.

A plurality of conductive traces 522, 524, 526, 528 are disposed about the magnetic core 520. A first conductive trace 522 is positioned in the second portion 512 and a second conductive trace 524 is positioned in the first portion 510. The first conductive trace 522 and second conductive trace 524 are connected through a first connection 550 and a second connection 552. The first connection 550 and the second connection 552 may be a via or a conductive trace. The first conductive trace 522 and second conductive trace 524 form one or more windings (one is shown) of a first coil 521 disposed around the first core cross section 520a. While the first coil 521 is shown with a single winding (loop), it will be understood that one or more additional windings (loops) of the first coil 521 may extend (wound) about the core 520 in a direction into and/or out of the plane of FIG. 5.

A third conductive trace 526 is positioned in the second portion 512 and a fourth conductive trace 528 is positioned in the first portion 510. The third conductive trace 526 and fourth conductive trace 528 are connected through a third connection 554 and a fourth connection 556. The third connection 554 and fourth connection 556 may be a via or a conductive trace. The third conductive trace 526 and fourth conductive trace 528 form one or more windings (one is shown) of a second coil 523 disposed around the second core cross section 520b. While the second coil 523 is shown with a single winding (loop), it will be understood that one or more additional windings (loops) of the second coil 523 may extend (wound) about the core 520 in a direction into and/or out of the plane of FIG. 5. The plurality of conductive traces 522, 524, 526, 528 which form the first and second coils and the magnetic core 520 are configured as a transformer. The second portion 512 is configured to encapsulate the surface of the first portion 510 and the transformer, to form a package body.

Anchors 542, 544, 546, 548 are positioned on either side of the recess 511. A first anchor 542 is positioned on the first portion 510 on a side of the first recess cross section 514 and a second anchor 544 is positioned on the first portion 510 on an opposing side of the first recess cross section 514. A third anchor 546 is positioned on the first portion 510 on a side of the second recess cross section 516 and a fourth anchor 548 is positioned on the first portion 510 on an opposing side of the second recess cross section 516. The anchors 542, 544, 546, 548 are not in contact with the magnetic core 520.

Support structures 560, 562, 564, 566 are disposed in the recess 511 and are connected to the magnetic core 520 and anchors 542, 544, 546, 548 disposed on the first portion 510 and second portion 512. The anchors 542, 544, 546, 548 are positioned adjacent to a third layer 534 of the magnetic core. The first layer 530 and the second layer 532 are positioned above the anchors 542, 544, 546, 548. The anchors 542, 544, 546, 548 are positioned below the fourth layer 536 and fifth layer 538. The anchors 542, 544, 546, 548 may have the same thickness or a different thickness than third layer 543 and anchors 542, 544, 546, 548. The support structures 560, 562, 564, 566 may have the same or a different thickness than third layer 543 and anchors 542, 544, 546, 548.

A first support structure 560 is disposed in the first recess cross section 514 and is connected to the first anchor 542 and the third layer 534. A second support structure 562 is disposed in the first recess cross section 514 and is connected to the second anchor 544 and the third layer 534. A third support structure 564 is disposed in the second recess cross section 516 and is connected to the third anchor 546 and the third layer 534. A fourth support structure 566 is disposed in the second recess cross section 516 and is connected to the fourth anchor 548 and the third layer 534. The support structures 560, 562, 564, 566 may extend from the first portion 510 to the magnetic core 520 in a straight shape.

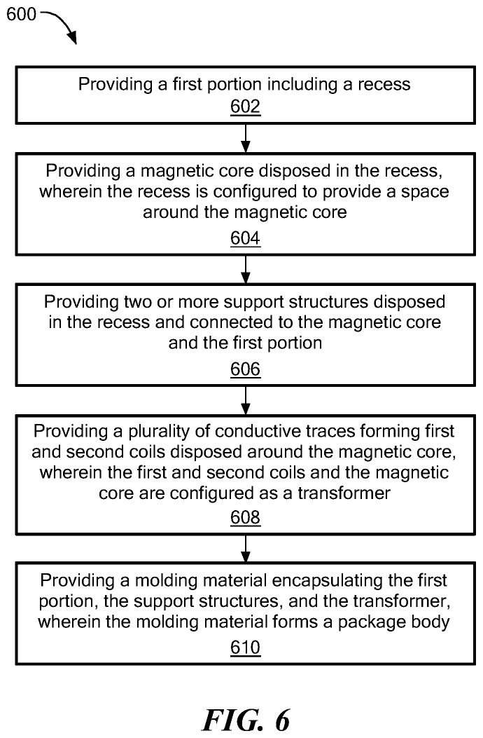

Referring now to FIG. 6, an example of a process to form a voltage isolated integrated circuit (IC) package configuration is a process 600. For example, the process 600 may be used to form the voltage isolated integrated circuit (IC) package configuration 100, 200, 300, 400, 500.

Process 600 provides a first portion including a recess (602). Process 600 provides a magnetic core disposed in the recess (604). The recess is configured to provide a space around the magnetic core. Process 600 provides two or more support structures disposed in the recess and connected to the magnetic core and the first portion (606). Process 600 provides a plurality of conductive traces forming first and second coils disposed around the magnetic core (608). The first and second coils and the magnetic core are configured as a transformer. Process 600 provides a molding material encapsulating the first portion, the support structures, and the transformer (610). The molding material forms a package body.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The term “one or more” is understood to include any integer number greater than or equal to one, e.g., one, two, three, four, etc.; though, where context admits, e.g., for a number of windings of a coil, the term can include fractional values, e.g., 1.5, 2.7, 3.3, etc. The term “a plurality” are understood to include any integer number greater than or equal to two, e.g., two, three, four, five, etc.; though, where context admits, e.g., for a number of windings of a coil, the term can include fractional values, e.g., 1.5, 2.7, 3.3, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A transformer based integrated circuit (IC) package, comprising:
a first portion including a recess;
a magnetic core disposed in the recess, wherein the recess is configured to provide a space between an interior surface of the recess and an exterior surface of the magnetic core, wherein the magnetic core includes a soft ferromagnetic material;
two or more support structures disposed in the recess and connected to the magnetic core and first portion;
a plurality of conductive traces forming first and second coils disposed about the magnetic core, wherein the first and second coils and magnetic core are configured as a transformer; and
a molding material configured to encapsulate a surface of the first portion and the transformer, wherein the molding material is configured to form a package body.

2. The IC package of claim 1, wherein the space comprises a gap between the interior surface of the recess and the exterior surface of the magnetic core.

3. The IC package of claim 1, wherein the first portion comprises a printed circuit board (PCB).

4. The IC package of claim 1, wherein the first portion comprises a molding material.

5. The IC package of claim 1, wherein the support structures are configured to reduce a mechanical stress on the magnetic core.

6. The IC package of claim 1, wherein the support structures extend from the first portion to the magnetic core in an L-shape.

7. The IC package of claim 1, wherein the support structures include two support structures, wherein the two support structures are both connected to a top side of the magnetic core.

8. The IC package of claim 1, wherein the magnetic core includes one or more layers.

9. The IC package of claim 8, wherein at least one of the one or more layers is a spacer layer.

10. The IC package of claim 8, further comprising a top layer, a middle layer, and a bottom layer, wherein the support structures are both connected to the middle layer of the magnetic core.

11. The IC package of claim 1, further comprising a second portion disposed on the first portion.

12. The IC package of claim 11, wherein the second portion comprises a printed circuit board (PCB).

13. The IC package of claim 11, wherein the second portion comprises a molding material.

14. A method of making a transformer based integrated circuit (IC) package, the method comprising:
providing a first portion including a recess;
providing a magnetic core disposed in the recess, wherein the recess is configured to provide a space between an interior surface of the recess and an exterior surface of the magnetic core, wherein the magnetic core includes a soft ferromagnetic material;
providing two or more support structures disposed in the recess and connected to the magnetic core and first portion;
providing a plurality of conductive traces forming first and second coils disposed about the magnetic core, wherein the first and second coils and magnetic core are configured as a transformer; and
providing a molding material configured to encapsulate a surface of the first portion and the transformer, wherein the molding material is configured to form a package body.

15. The method of claim 14, wherein the space comprises a gap between the interior surface of the recess and the exterior surface of the magnetic core.

16. The method of claim 14, wherein the first portion comprises a printed circuit board (PCB).

17. The method of claim 14, wherein the first portion comprises a molding material.

18. The method of claim 14, wherein the support structures are configured to reduce a mechanical stress on the magnetic core.

19. The method of claim 14, wherein the support structures extend from the first portion to the magnetic core in an L-shape.

20. The method of claim 14, wherein the support structures include two support structures, wherein the two support structures are both connected to a top side of the magnetic core.

21. The method of claim 14, wherein the magnetic core includes a one or more layers.

22. The method of claim 21, wherein at least one of the one or more layers is a spacer layer.

23. The method of claim 21, further comprising a top layer, a middle layer, and a bottom layer, wherein the support structures are both connected to the middle layer of the magnetic core.

24. The method of claim 14, further comprising providing a second portion on the first portion.

25. The method of claim 24, wherein the second portion comprises a printed circuit board (PCB).

26. The method of claim 24, wherein the second portion comprises a molding material.
